(19) United States
(12) Patent Application Publication
(10) Pub. No.: US 2026/0104442 A1
(43) Pub. Date: Apr. 16, 2026

(54) METHOD FOR MEASURING THE PHASE OF A COMPLEX IMPEDANCE AND MEASURING DEVICE

(71) Applicant: COMMISSARIAT À L'ENERGIE ATOMIQUE ET AUX ENERGIES ALTERNATIVES, PARIS (FR)

(72) Inventor: Esteban CABANILLAS, GRENOBLE (FR)

(21) Appl. No.: 19/337,879

(22) Filed: Sep. 23, 2025

(30) Foreign Application Priority Data
Oct. 16, 2024 (FR) 2411233

(51) Int. Cl. G01R 25/00; G04F 10/00

(52) U.S. Cl. CPC G01R 25/005; G04F 10/005

(57) ABSTRACT

A method for measuring the phase of a complex impedance of an electrical element, includes the following steps of: applying an excitation signal to the electrical element; acquiring a first analogue signal; acquiring a second analogue signal; digitising the first analogue signal into a first digital signal and the second analogue signal into a second digital signal; injecting the first digital signal into the start input of a first time-to-digital converter and into the stop input of a second time-to-digital converter; injecting the second digital signal into the stop input of the first time-to-digital converter and into the start input of the second time-to-digital converter; determining a first delay value t₁ and a second delay value t₂; computing the value of the phase of the complex impedance of the electrical element.

### CROSS-REFERENCE TO RELATED APPLICATION

This application claims priority to foreign French patent application No. FR 2411233, filed on Oct. 16, 2024, the disclosure of which is incorporated by reference in its entirety.

### FIELD OF THE INVENTION

The invention is in the field of electronic instrumentation. More specifically, it relates to a method and a device for measuring a complex impedance of an electrical element.

### BACKGROUND

The notion of complex impedance generalises that of resistance for sinusoidal signals at a given frequency f. In the case of an electrical dipole, the complex impedance Z is defined by Z=U/I, where U is the phasor (complex number) representing the amplitude and the phase of the voltage across the terminals of the dipole and I is the phasor representing the amplitude and the phase of the current flowing through it. More generally, in the case of a circuit with N ports (with the dipole corresponding to the case whereby N=1), an impedance Zᵢⱼ=Uᵢ/Iⱼ|_{I}_{ₖ}_{=0,k≠j} can be defined. In other words, the impedance Zᵢⱼ is the (complex) ratio between the phasor representing the voltage across the terminals of the port “i” and the phasor representing the current entering (or exiting, depending on the adopted convention) the port “j” when the current entering all the other ports is zero. The different terms Zᵢⱼ form the impedance matrix of the multiport element. Hereafter, the term impedance and the “Z” symbol will be used to refer to both the impedance of a dipole and a term Zᵢⱼ of the impedance matrix of a multiport.

As it is a complex number, the impedance Z of an electrical element can be broken down into a real part and an imaginary part—Z=R+jX, where “j” in this case denotes the imaginary unit—or into a modulus and a phase: Z=|Z|e^{jφ}, where |Z| is the ratio between the effective values of the voltage and the current and φ is their phase shift. The phase of the impedance corresponds to the delay that exists between the voltage across the terminals of the electrical element and the current flowing through the electrical element.

In general, the impedance varies with the frequency of the considered electrical signals. In order to characterise an electrical element, the one or more impedances thereof therefore need to be measured over a fairly extended frequency band. Therefore, Z(f), |Z(f)| and φ(f) are written to respectively denote a complex impedance, its modulus and its phase as a function of the frequency f (or, similarly, as a function of its period T=1/f).

Several techniques have been developed to measure the phase of the impedance, φ(f), of an electrical element as a function of the frequency.

Among the known methods of the prior art, the delay î(f) (or phase shift φ(f), if multiplied by 2π/T) between the digitised signals Ū_{V} and Ū_{I} of the voltage uᵥ across the terminals of the electrical element and the current uᵢ flowing through it is measured using a time-to-digital converter (TDC) comprising N delay elements, where each delay element has a transition time τ.

This TDC architecture is a conventional architecture that can be easily implemented, particularly in systems based on field-programmable gate arrays (FPGA).

The complexity of integrating a TDC into an FPGA depends on multiple factors:

The transition time τ of the logic element of the delay line. A small value for τ allows very accurate time measurements to be taken, but can lead to overly complex integration of the TDC if the time dynamics to be measured are much greater than τ. The minimum value of τ is defined by the targeted FPGA technology.

The maximum frequency fₘₐₓ to be generated in order to perform the frequency scan for the impedance phase measurement. A high frequency yields short period values and therefore small delays to be measured, which requires a very small value for τ for accurate measurements. The accuracy in the estimation of φ(f) therefore will be determined by the FPGA that is used.

The minimum frequency fₘᵢₙ to be generated in order to perform the frequency scan for the impedance phase measurement. A low frequency is associated with high periods and, therefore, for a full dynamic phase measurement (0-2π), with a very complex TDC in terms of the number of delay elements and triggers.

Therefore, a compromise needs to be found between the measurement dynamics (fₘₐₓ−fₘᵢₙ) and the resolution of the TDC determined by the value τ.

To measure a phase range from 0 to 2π, a delay line needs to be designed comprising a large number of delay elements. FPGA integration therefore exhibits significant dispersion phenomena due to the non-uniformity of the logic cells and the internal routing of signals and blocks within the FPGA.

The phase estimation error Δφ(f) also exhibits significant asymmetry with respect to the estimated phase (see FIG. 4), which is detrimental for the post-processing algorithms.

(Mattada et al. 2021) propose a system for reducing the phase estimation error by using complex TDCs designed from multiple phase-locked loop (PLL) counters and delay-locked loop (DLL) counters.

Furthermore, no prior art document addresses the imperfections that cause asymmetry in the phase estimation error.

Therefore, a requirement exists for making the phase estimation error symmetrical and low within the context of integrating conventional TDCs into an FPGA.

### BRIEF DESCRIPTION OF THE DRAWINGS

Further features, details and advantages of the invention will become apparent from reading the description that is provided with reference to the accompanying drawings, which are provided by way of example and respectively represent:

FIG. 1 shows the functional diagram of a measuring device not forming part of the invention;

FIG. 2 is an illustration of the operating principle of the device shown in FIG. 1;

FIG. 3 is a functional diagram of a phase measuring device based on a TDC using a delay line;

FIG. 4 is a graph illustrating the dependence of said phase measurement error as a function of the phase of the measured complex impedance;

FIG. 5 is a functional diagram of a measuring device according to one embodiment of the invention;

FIG. 6 is a functional diagram of a measuring device according to another embodiment of the invention.

### DETAILED DESCRIPTION

In the algorithms throughout the remainder of the description, the “&” symbol is equivalent to the “AND” logical operator, and the “|” symbol is equivalent to the “OR” logical operator.

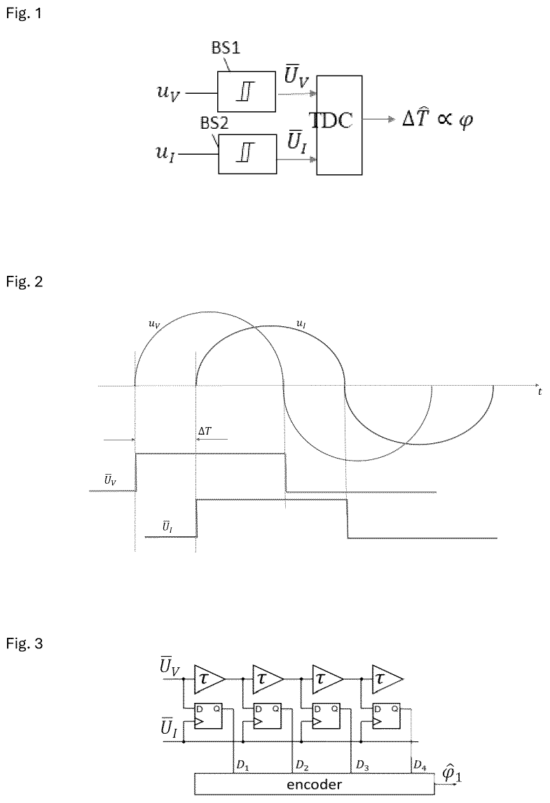

FIG. 1 shows the functional diagram of a hypothetical measuring device that, in principle, allows the phase shift to be measured between two sinusoidal analogue signals uᵥ and uᵢ. If these two signals respectively represent the voltage across the terminals of an electrical element and the current flowing through it, this phase shift measurement can be used to determine the phase of the complex impedance of the element.

The device in FIG. 1 comprises two Schmitt triggers BS1, BS2 with two threshold voltages V_{LH}>0V and V_{HL}<0V. The output of a Schmitt trigger becomes high when the signal at its input exceeds V_{LH}, and then remains high while said signal falls below V_{HL}. For V_{LH}→0V and V_{HL}→0V, the Schmitt trigger becomes a simple zero comparator. If such a comparator was used, electronic noise would induce multiple and random switching when the input signal passes through zero; for this reason, Schmitt triggers, also called hysteresis comparators, are generally preferred, with a hysteresis ΔV=V_{LH}−V_{HL} of the same order of magnitude as the peak amplitude of the noise affecting the input signal.

Schmitt triggers convert the sinusoidal input signals uᵥ and uᵢ into two slot signals Ū_{V} and Ū_{I}, respectively. A time-to-digital converter (TDC) receives these signals as input and outputs a digital value Δ\hat{T} that is an estimate of the time lag ΔT between the rising edges (or, similarly, the falling edges) of these signals. As can be seen in FIG. 2, this time lag is in turn proportional to the phase shift φ between the two analogue input signals uᵥ and uᵢ. Furthermore, the digital output of the TDC converter is (to the nearest multiplicative factor, equal to the frequency f of the input signals) an estimate \hat{φ} of this phase shift.

The operating principle of a TDC involves measuring, in multiples of time units τ, the delay between the signals Ū_{V} and Ū_{I}. To this end, the signal Ū_{V} is injected into a delay line comprising N delay elements, where each delay element has a transition time τ, as can be seen in FIG. 3. This delay element can be implemented using a logic gate (for example, NOT, OR, AND) or an arithmetic block (for example, adder, multiplier), or any other asynchronous logic block with a fixed delay. The time is measured when the rising edge of Ū_{I} occurs. At this instant, the output state of each delay element is recorded at the output of the triggers. The delay \hat{τ} between the rising edges of Ū_{V} and Ū_{I} is approximated by \hat{τ}=Nτ, with N being the position of the trigger where a transition of the output value from logic “1” to logic “0” occurs. The frequency φ(f) is estimated using prior knowledge of the frequency (and the period) of the signal U_{V}, which is generated by the measurement system.

For a TDC integrated into a Xilinx ZYNQ 7010 type FPGA, the delay element is a 2-bit adder with carry, with a transition time of τ=585 ps. The TDC is designed to operate at frequencies ranging from 6 MHz to 10 MHz. With a minimum frequency of around 6 MHz (period T=166 ns), a delay line of approximately 300 elements needs to be integrated in order to be able to measure a phase range of 0 to 2π. As explained above, such an FPGA integration is associated with significant dispersion phenomena due to the non-uniformity of the logic cells and the internal routing of signals and blocks within the FPGA.

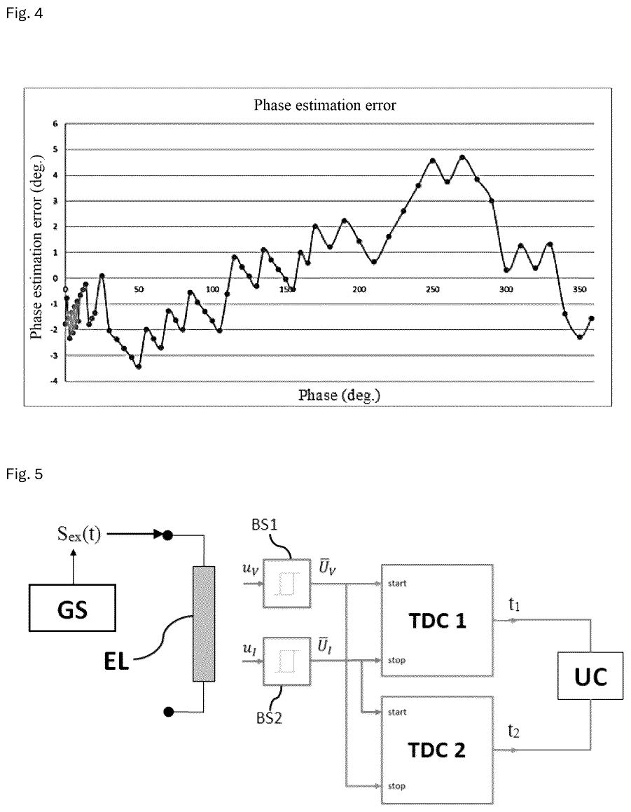

For a transition time of τ=585 ps and a signal [symbol] injected at a frequency of f=8.5 MHz, the resolution provided by the transition time τ represents a phase of 1.8°. As shown in FIG. 4, in this configuration, the error is less than the resolution for the measurement interval over the interval [0°-40°]. Subsequently, dispersion generates an error of 2 times the resolution over the interval [40°-250°]. Over the interval [250°-360°], the error is greater than 3 times the resolution.

One underlying idea of the invention is that a different TDC for each phase interval can be used to reduce the phase estimation error.

FIG. 5 illustrates the functional diagram of a device according to a first embodiment of the invention, implementing this principle.

In FIG. 5, the reference EL represents an electrical element (more specifically, a dipole, comprising two terminals forming a single port) whose complex impedance phase must be determined. A generator GS applies a sinusoidal excitation signal Sₑₓₜ(t), with an optionally variable frequency f, to the terminals of the element EL. The signal Sₑₓₜ(t) can be a current or voltage signal. The generator GS also outputs a digital value representing the frequency f. The generator GS can be controlled, for example, in such a way that f continuously or discretely scans a spectral band of interest.

The device in FIG. 5 receives the first analogue signal u_{V}(t) on a first input port that represents the voltage across the terminals of the element EL and receives the second analogue signal uᵢ(t) on a second input port that represents the current flowing through the latter. For example, the signal uᵥ(t) directly can be the voltage across the terminals of the element EL and uᵢ(t) can be a voltage across the terminals of a resistor connected in series with EL. The signals uᵥ(t) and uᵢ(t) are supplied to respective Schmitt triggers BS1 and BS2 as input, which output slot signals Ū_{V}, Ū_{I}.

The output of the first Schmitt trigger BS1 is connected to the “START” input of a first time-to-digital converter TDC1 and to the “STOP” input of a second time-to-digital converter TDC2 of the device in FIG. 5. Preferably, the output of the first Schmitt trigger BS1 is directly connected to the start input of TDC1 and to the stop input of TDC2 in such a way that no other diode is connected in series between BS1 and the start input of TDC1 or between BS1 and the stop input of TDC2. Alternatively, a dipole is connected in series between BS1 and the start input of TDC1 or between BS1 and the stop input of TDC2. The dipole is a current sensor, for example.

The output of the second Schmitt trigger BS2 is connected to the stop input of the first time-to-digital converter TDC1 and to the start input of the second time-to-digital converter TDC2. Preferably, the output of the second Schmitt trigger BS1 is directly connected to the stop input of TDC1 and to the start input of TDC2 in such a way that no other dipole is connected in series between BS2 and the stop input of TDC1 or between BS2 and the start input of TDC2. Alternatively, a dipole is connected in series between BS2 and the stop input of TDC1 or between BS2 and the start input of TDC2. The dipole is a current sensor, for example.

The first time-to-digital converter TDC1 is configured to measure a delay value t₁ between the rising edge of the digital signal injected at the start input and the rising edge of the digital signal injected at the stop input. Similarly, the first time-to-digital converter TDC1 is configured to measure a delay value t₁ between the falling edge of the digital signal injected at the start input and the falling edge of the digital signal injected at the stop input.

The second time-to-digital converter TDC2 is configured to measure a delay value t₂ between the rising edge of the digital signal injected at the stop input and the rising edge of the digital signal injected at the start input. Similarly, the second time-to-digital converter TDC2 is configured to measure a delay value t₁ between the falling edge of the digital signal injected at the stop input and the falling edge of the digital signal injected at the start input.

The device in FIG. 5 also comprises a computation unit UC configured to compute the value of the phase of the complex impedance of the electrical element EL, either as a function of t₁ for t₁≤S₀, or as a function of t₂ for S₁≤t₁≤S₂, where S₀, S₁ and S₂ are three threshold values, with S₀≤S₁≤S₂.

As explained above, the delay is estimated by the formula \hat{t}=Nτ. When t₁≤S₀, the delay \hat{t} is equal to the time t₁, with t₁ being computed from the first time-to-digital converter TDC1, which is in a conventional configuration, measuring a delay value between the rising edge of Ū_{I} and the rising edge of Ū_{V}.

When S₁≤t₁≤S₂, the delay \hat{t} is equal to (S₂−t₂), with t₂ being computed from the second time-to-digital converter TDC2, which is in a configuration opposite that of the first time-to-digital converter TDC1. In this configuration, the second time-to-digital converter TDC2 measures a delay value between the rising edge of Ū_{V} and the rising edge of Ū_{I}. Consequently, the value Nτ measured by the second time-to-digital converter TDC2 corresponds to the value (S2−\hat{t}).

Preferably, S₀=S₁=T/2 and S₂=T. For t₁≤T/2, the delay \hat{t} is equal to the time t₁. For T/2≤t₁≤T or t₁=0, the delay value \hat{t} is equal to (T−t₂). For phases less than 180°, the delay t is evaluated by the first time-to-digital converter TDC1, which measures the delay of the rising edge of Ū_{V} relative to the rising edge of Ū_{I}. For phases greater than 180°, the delay \hat{t} is evaluated by the second time-to-digital converter TDC2, which measures the delay of the rising edge of Ū_{I} relative to the rising edge of Ū_{V}.

The time-to-digital converter TDC1 is configured to return a zero value (t₁=0) when the measured delay value is greater than half the period of the first digital signal Ū_{V}.

According to the first embodiment of the invention, the measurement algorithm for estimating the delay \hat{t} is as follows:

$$( {t}_{1} < \frac{T}{2} ) \to \hat{t} = {t}_{1}$$

$$( {t}_{1} > \frac{T}{2} ) \vert ( {t}_{1} == 0 ) \to \hat{t} = T - {t}_{2}$$

According to the first embodiment, all the TDCs must only be able to measure a delay value up to Tₘₐₓ/2.

Advantageously, the delay t₁ or t₂ used for evaluating the delay \hat{t} is always less than 180° for a frequency of the first digital signal Ū_{V} that is equal to fₘᵢₙ. The measured delay t can be greater than 180° if the frequency of the first digital signal Ū_{V} is greater than fₘᵢₙ. This allows the complexity of the TDCs that are used to be limited, particularly in terms of the number of delay elements, and allows the error in estimating the phase of the impedance of the electrical element EL to be reduced. The invention also allows the error in estimating the phase of the impedance of the electrical element EL to be rendered more phase symmetrical.

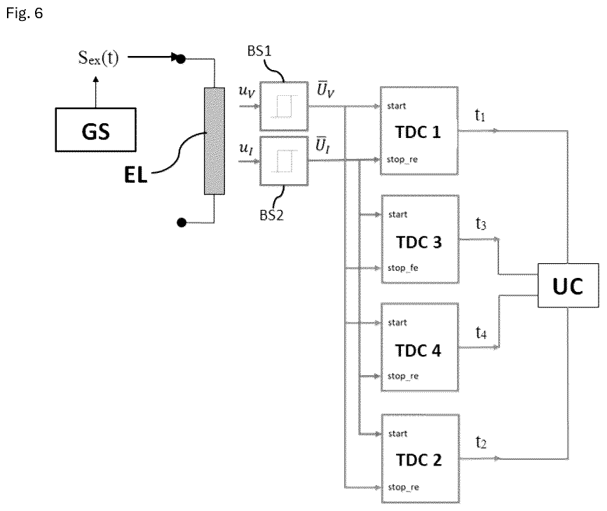

FIG. 6 illustrates the functional diagram of a device according to a second embodiment of the invention, implementing this principle.

According to this embodiment, the device also comprises, compared to the first embodiment, a third time-to-digital converter TDC3 and a fourth time-to-digital converter TDC4.

The output of the first Schmitt trigger BS1 is connected to the start input of the fourth time-to-digital converter TDC4 and to the stop input of the third time-to-digital converter TDC3 of the device in FIG. 5. Preferably, the output of the first Schmitt trigger BS1 is directly connected to the start input of TDC4 and to the stop input of TDC3 in such a way that no other dipole is connected in series between BS1 and the start input of TDC4 or between BS1 and the stop input of TDC3. Alternatively, a dipole is connected in series between BS1 and the start input of TDC4 or between BS1 and the stop input of TDC3. The dipole is a current sensor, for example.

The output of the second Schmitt trigger BS2 is connected to the stop input of the fourth time-to-digital converter TDC4 and to the start input of the third time-to-digital converter TDC3. Preferably, the output of the second Schmitt trigger BS1 is directly connected to the stop input of TDC4 and to the start input of TDC3 in such a way that no other dipole is connected in series between BS2 and the stop input of TDC4 or between BS2 and the start input of TDC3. Alternatively, a dipole is connected in series between BS2 and the stop input of TDC4 or between BS2 and the start input of TDC3. The dipole is a current sensor, for example.

The third time-to-digital converter TDC3 is configured to measure a delay value t₃ between the rising edge of the digital signal injected at the start input and the falling edge of the digital signal injected at the stop input. Similarly, the third time-to-digital converter TDC3 is configured to measure a delay value t₃ between the falling edge of the digital signal injected at the start input and the rising edge of the digital signal injected at the stop input.

The fourth time-to-digital converter TDC4 is configured to measure a delay value t₄ between the falling edge of the digital signal injected at the stop input and the rising edge of the digital signal injected at the start input. Similarly, the fourth time-to-digital converter TDC4 is configured to measure a delay value t₄ between the rising edge of the digital signal injected at the stop input and the falling edge of the digital signal injected at the start input.

As described above, for TDCs 1, 2 and 4, the delay \hat{t} between the rising or falling edges of Ū_{V} and Ū_{I} is approximated by \hat{t}=Nτ, with N being the position of the trigger where a transition of the output value from logic “1” to logic “0” occurs. For TDC3, the delay \hat{t} between the falling edge of the digital signal Ū_{V} injected at the start input (Ū_{V}) and the rising edge of the digital signal Ū_{I} injected at the stop input is approximated by \hat{t}=Nτ, with N being the position of the trigger where a transition of the output value from logic “0” to logic “1” occurs.

In this embodiment, the computation unit UC is configured to compute the value of the phase of the complex impedance of the electrical element EL, either as a function of t₁ for t₁≤S₀, or as a function of t₂ for S₁≤t₁≤S₂, or as a function of t₃ for S₀≤t₁≤S_{0′}, or as a function of t₄ for S_{0′}≤t₁≤S₁, where S₀, S_{0′}, S₁ and S₂ are four threshold values, with S₀≤S_{0′}≤S₁≤S₂.

Preferably, S₀=T/4, S_{0′}=T/2, S₁=3T/4 and S₂=T. For t₁≤T/4, the delay \hat{t} is equal to the time t₁. For T/4≤t₁≤T/2, the delay value \hat{t} is equal to (T/2−t₃). For T/2≤t₁≤3T/4, the delay value \hat{t} is equal to (T/2+t₄). For 3T/4≤t₁≤T, the delay value \hat{t} is equal to (T−t₂).

According to a first variant of the second embodiment, the measurement algorithm for estimating the delay \hat{t} is as follows:

$$( {t}_{1} < \frac{T}{4} ) \to \hat{t} = {t}_{1}$$

$$( {t}_{1} > \frac{T}{4} ) \& ( {t}_{1} < \frac{T}{2} ) \to \hat{t} = \frac{T}{2} - {t}_{3}$$

$$( {t}_{1} > \frac{T}{2} ) \& ( {t}_{1} < \frac{3 T}{4} ) \to \hat{t} = \frac{T}{2} + {t}_{4}$$

$$( {t}_{1} > \frac{3 T}{4} ) \to \hat{t} = T - {t}_{2}$$

According to the first variant of the second embodiment, TDC 1 must be able to measure a delay value up to Tₘₐₓ, while TDCs 2, 3 and 4 must be able to measure a delay value up to Tₘₐₓ/4.

Advantageously, the delay t₁, t₂, t₃ or t₄ used for evaluating the delay \hat{t} is always less than 90° for a frequency of the first digital signal Ū_{V} that is equal to fₘᵢₙ. The measured delay t can be greater than 90° if the frequency of the first digital signal Û_{V} is greater than fₘᵢₙ. This allows the complexity of the TDCs that are used to be limited, particularly in terms of the number of delay elements, and allows the error in estimating the phase of the impedance of the electrical element EL to be reduced. The invention also allows the error in estimating the phase of the impedance of the electrical element EL to be rendered more phase symmetrical.

According to a second variant of the second embodiment, the time-to-digital converter TDC1 (respectively TDC2, TDC3) is configured to return a zero value when the measured delay value t₁ (respectively t₂, t₃) is greater than a quarter of the period of the first digital signal Ū_{V}. The value of the phase of the complex impedance of the electrical element is determined either as a function of the delay value t₁ for t₁<T/4, or as a function of t₃ for (t₁>T/4 or t₁=0) and t₃<T/4, or as a function of t₄ for (t₁>T/4 or t₁=0), (t₃>T/4 or t₃=0) and t₄<T/4, or as a function of t₂ for (t₁>T/4 or t₁=0), (t₃>T/4 or t₃=0), (t₄>T/4 or t₄=0) and t₂<T/4.

According to the second variant of the second embodiment, the measurement algorithm for estimating the delay \hat{t} is as follows:

$$( {t}_{1} < \frac{T}{4} ) \to \hat{t} = {t}_{1}$$

$$( ( {t}_{1} > \frac{T}{4} ) \vert ( {t}_{1} == 0 ) ) \& ( {t}_{3} < \frac{T}{4} ) \to \hat{t} = \frac{T}{2} - {t}_{3}$$

$$( ( {t}_{1} > \frac{T}{4} ) \vert ( {t}_{1} == 0 ) ) \& ( ( {t}_{3} > \frac{T}{4} ) \vert ( {t}_{3} == 0 ) ) \& ( {t}_{4} < \frac{T}{4} ) \to \hat{t} = \frac{T}{2} + {t}_{4}$$

$$( ( {t}_{1} > \frac{T}{4} ) \vert ( {t}_{1} == 0 ) ) \& ( ( {t}_{3} > \frac{T}{4} ) \vert ( {t}_{3} == 0 ) ) \& ( ( {t}_{4} > \frac{T}{4} ) \vert ( t == 0 ) ) \to \hat{t} = T - {t}_{2}$$

According to the second variant of the second embodiment, all the TDCs must only be able to measure a delay value up to Tₘₐₓ/4. Advantageously, this allows the complexity of the TDCs that are used to be reduced.

The time-to-digital converters TDC1, TDC2, TDC3 are thus less complex because their measuring range is 0° to 90°.

The invention also relates to a method for measuring the phase of a complex impedance of an electrical element EL. The method can be implemented by a device according to one of the embodiments described above.

According to a first embodiment of the invention, the method comprises the following steps:
an excitation step S11, during which an excitation signal Sₑₓ oscillating at a known period T is applied to the electrical element EL;
a first acquisition step S21, during which a first analogue signal uᵥ, which is variable over time and represents a voltage across the terminals of the electrical element EL, is acquired;
a second acquisition step S22, during which a second analogue signal uᵢ, which is variable over time and represents a current through the electrical element EL, is acquired;
a digitisation step S31, during which the first analogue signal uᵥ is digitised into a first digital signal Ū_{V} and the second analogue signal (uᵢ) is digitised into a second digital signal Ū_{I};
a first injection step S41, during which the first digital signal [symbol] is injected into the start input of a first time-to-digital converter and into the stop input of a second time-to-digital converter;
a second injection step S42, during which the second digital signal Ū_{I} is injected into the stop input of the first time-to-digital converter and into the start input of the second time-to-digital converter;
a first determination step S51, during which a first delay value t₁ between the rising or falling edge, respectively, of the digital signal injected into the start input and the rising or falling edge, respectively, of the digital signal injected into the stop input of the first digital delay converter is determined, and a second delay value t₂ between the rising or falling edge, respectively, of the digital signal injected into the start input and the rising or falling edge, respectively, of the digital signal injected into the stop input of the second time-to-digital converter is determined;
a first computation step S61, during which the value of the phase of the complex impedance of the electrical element is computed, either as a function of t₁ for t₁≤S₀, or as a function of t₂ for S₁≤t₁≤S₂, where S₀, S₁ and S₂ are three threshold values, with S₀≤S₁≤S₂.

Preferably, S₀=S₁=T/2 and S₂=T.

Preferably, the delay value t₁ is assigned a zero value when the measured delay value t₁ is greater than half the period of the first digital signal Ū_{V}.

According to the first embodiment of the invention, the measurement algorithm for estimating the delay \hat{t} is as follows:

$$( {t}_{1} < \frac{T}{2} ) \to \hat{t} = {t}_{1}$$

$$( {t}_{1} > \frac{T}{2} ) \vert ( {t}_{1} == 0 ) \to \hat{t} = T - {t}_{2}$$

According to a second embodiment of the invention, the measurement method also comprises:
a third injection step S43, during which the second digital signal Ū_{I} is injected into the start input of a third time-to-digital converter and into the stop input of a fourth time-to-digital converter. The third injection step S43 occurs after the second injection step S42 and before the first determination step S51;
a fourth injection step S44, during which the first digital signal Ū_{V} is injected into the stop input of the third time-to-digital converter and into the start input of the fourth time-to-digital converter. The fourth injection step S44 occurs after the third injection step S43 and before the first determination step S51;
a second determination step S52, during which a third delay value t₃ between the rising or falling edge, respectively, of the digital signal injected into the start input and the falling or rising edge, respectively, of the digital signal injected into the stop input of the third time-to-digital converter is determined, and a fourth delay value t₄ between the falling or rising edge, respectively, of the digital signal injected into the start input and the rising or falling edge, respectively, of the digital signal injected into the stop input of the fourth time-to-digital converter is determined;
a second computation step S62, during which the value of the phase of the complex impedance of the electrical element is computed, either as a function of t₃ for S₀≤t₁≤S_{0′}, or as a function of t₄ for S_{0′}≤t₁≤S₁, where S_{0′} is a threshold value, with S₀≤S_{0′}≤S₁≤S₂.

Preferably, S₀=T/4, S_{0′}=T/2 and S₁=3T/4 and S₂=T.

According to a first variant of the second embodiment, the measurement algorithm for estimating the delay \hat{t} is as follows:

$$( {t}_{1} < \frac{T}{4} ) \to \hat{t} = {t}_{1}$$

$$( {t}_{1} > \frac{T}{4} ) \& ( {t}_{1} < \frac{T}{2} ) \to \hat{t} = \frac{T}{2} - {t}_{3}$$

$$( {t}_{1} > \frac{T}{2} ) \& ( {t}_{1} < \frac{3 T}{4} ) \to \hat{t} = \frac{T}{2} + {t}_{4}$$

$$( {t}_{1} > \frac{3 T}{4} ) \to \hat{t} = T - {t}_{2}$$

According to a second variant of the second embodiment, the delay values are assigned a zero value when they are greater than T/4, and wherein the value of the phase of the complex impedance of the electrical element is computed, either as a function of the delay value t₁ for t₁<T/4, or as a function of t₃ for (t₁>T/4 or t₁=0) and t₃<T/4, or as a function of t₄ for (t₁>T/4 or t₁=0), (t₃>T/4 or t₃=0) and t₄<T/4, or as a function of t₂ for (t₁>T/4 or t₁=0), (t₃>T/4 or t₃=0), (t₄>T/4 or t₄=0) and t₂<T/4.

According to the second variant of the second embodiment, the measurement algorithm for estimating the delay \hat{t} is as follows:

$$( {t}_{1} < \frac{T}{4} ) \to \hat{t} = {t}_{1}$$

$$( ( {t}_{1} > \frac{T}{4} ) \vert ( {t}_{1} == 0 ) ) \& ( {t}_{3} < \frac{T}{4} ) \to \hat{t} = \frac{T}{2} - {t}_{3}$$

$$( ( {t}_{1} > \frac{T}{4} ) \vert ( {t}_{1} == 0 ) ) \& ( ( {t}_{3} > \frac{T}{4} ) \vert ( {t}_{3} == 0 ) ) \& ( {t}_{4} < \frac{T}{4} ) \to \hat{t} = \frac{T}{2} + {t}_{4}$$

$$( ( {t}_{1} > \frac{T}{4} ) \vert ( {t}_{1} == 0 ) ) \& ( ( {t}_{3} > \frac{T}{4} ) \vert ( {t}_{3} == 0 ) ) \& ( ( {t}_{4} > \frac{T}{4} ) \vert ( t == 0 ) ) \to \hat{t} = T - {t}_{2}$$

The invention has been described with reference to specific embodiments, but variants are possible. For example:

The threshold values can be S₀=T/3, S_{0′}=T/2 and S₁=2T/3 and S₂=T.

Advantageously, such a configuration with non-symmetrical measurement ranges between each TDC (in this variant, the measurement ranges of TDC3 and TDC4 would be smaller than the measurement ranges of TDC1 and TDC2) would allow the use of TDCs with a larger number of delay elements (or a smaller transition time τ) for a smaller measurement range. This would allow the measurement elements to be concentrated (or the measurement elements with the smallest transition times t to be used) at the most relevant intervals and would allow the asymmetry of the phase measurement error to be taken into account more effectively as a function of the phase described above and shown in FIG. 4, while limiting the total number of measurement elements over the interval [0°-360°]. Other threshold values can be selected in order to better take into account the behaviour of the TDCs that are used and the frequency bands that are used for the impedance measurement.

The device can be integrated into an ASIC (“Application-Specific Integrated Circuit”) system.

### REFERENCES

(Mattada et al., 2021): M. Mattada, H. Guhilot, 62.5 ps LSB resolution multiphase clock Time to Digital Converter (TDC) implemented on FPGA, Journal of King Saud University-Engineering Sciences, Volume 34, Issue 6, 2022, Pages 418-424.

1. A device for measuring the phase of a complex impedance of an electrical element (EL) comprising:
a first Schmitt trigger (BS1) configured to receive a first analogue signal (uᵥ) as input that is variable over time, of period T, representing a voltage between two terminals of the electrical element, and to convert it into a first digital signal (Ūᵥ);
a second Schmitt trigger (BS2) configured to receive a second analogue signal (u_{I}) that is variable over time, representing a current through the electrical element, and to convert it into a second digital signal (Ū_{I});
a first time-to-digital converter (TDC1);
a second time-to-digital converter (TDC2);
a computation unit (UC);
the output of the first Schmitt trigger (BS1) being directly or indirectly connected to the start input of the first time-to-digital converter (TDC1) and to the stop input of the second time-to-digital converter (TDC2),
the output of the second Schmitt trigger (BS2) being directly or indirectly connected to the stop input of the first time-to-digital converter (TDC1) and to the start input of the second time-to-digital converter (TDC2),
the first time-to-digital converter (TDC1) being configured to measure a delay value t₁ between the rising or falling edge, respectively, of the digital signal injected at the start input and the rising or falling edge, respectively, of the digital signal injected at the stop input,
the second time-to-digital converter (TDC2) being configured to measure a delay value t₂ between the rising or falling edge, respectively, of the digital signal injected at the stop input and the rising or falling edge, respectively, of the digital signal injected at the start input,
the computation unit (UC) being configured to compute the value of the phase of the complex impedance of the electrical element, either as a function of t₁ for t₁≤S₀, or as a function of t₂ for S₁≤t₁S₂, where S₀, S₁ and S₂ are three threshold values, with S₀≤S₁≤S₂.

2. The device according to claim 1, wherein S₀=S₁=T/2 and S₂=T.

3. The device for measuring the phase of a complex impedance of an electrical element (EL) according to claim 2, further comprising:
a third time-to-digital converter (TDC3);
a fourth time-to-digital converter (TDC4);
the output of the first Schmitt trigger (BS1) being directly or indirectly connected to the start input of the fourth time-to-digital converter (TDC4) and to the stop input of the third time-to-digital converter (TDC3),
the output of the second Schmitt trigger (BS2) being directly or indirectly connected to the start input of the third time-to-digital converter (TDC3) and to the stop input of the fourth time-to-digital converter (TDC4),
the third time-to-digital converter (TDC3) being configured to measure a delay value t₃ between the rising or falling edge, respectively, of the digital signal injected at the start input and the falling or rising edge, respectively, of the digital signal injected at the stop input,
the fourth time-to-digital converter (TDC4) being configured to measure a delay value t₄ between the falling or rising edge, respectively, of the digital signal injected at the start input and the rising or falling edge, respectively, of the digital signal injected at the stop input,
the computation unit (UC) being configured to compute the value of the phase of the complex impedance of the electrical element, either as a function of t₃ for S₀≤t₁≤S_{0′}, or as a function of t₄ for S_{0′}≤t₁≤S₁, where S_{0′} is a threshold value, with S₀≤S_{0′}≤S₁≤S₂.

4. The device according to claim 3, wherein S₀=T/4, S_{0′}=T/2, S₁=3T/4 and S₂=T.

5. The device according to claim 4, wherein the time-to-digital converters are configured to return a zero value when the measured delay value is greater than T/4, and wherein the value of the phase of the complex impedance of the electrical element is determined either as a function of the delay value t₁ for t₁<T/4, or as a function of t₃ for (t₁>T/4 or t₁=0) and t₃<T/4, or as a function of t₄ for (t₁>T/4 or t₁=0), (t₃>T/4 or t₃=0) and t₄<T/4, or as a function of t₂ for (t₁>T/4 or t₁=0), (t₃>T/4 or t₃=0), (t₄>T/4 or t₄=0) and t₂<T/4.

6. The device according to claim 1, wherein the device is integrated into an FPGA system.

7. A method for measuring the phase of a complex impedance of an electrical element (EL), comprising the following steps of:
a) applying an excitation signal (Sₑₓ) to the electrical element (EL) that oscillates at a known period T;
b) acquiring a first analogue signal (u_{V}) that is variable over time, representing a voltage across the terminals of the electrical element;
c) acquiring a second analogue signal (u_{I}) that is variable over time, representing a current through the electrical element;
d) digitising the first analogue signal (u_{V}) into a first digital signal (U_{V}) and the second analogue signal (u_{I}) into a second digital signal (Ū_{I});
e) injecting the first digital signal (Ūᵥ) into the start input of a first time-to-digital converter and into the stop input of a second time-to-digital converter;
f) injecting the second digital signal (Ū_{I}) into the stop input of the first time-to-digital converter and into the start input of the second time-to-digital converter;
g) determining a first delay value t₁ between the rising or falling edge, respectively, of the digital signal injected into the start input and the rising or falling edge, respectively, of the digital signal injected into the stop input of the first digital delay converter, and a second delay value t₂ between the rising or falling edge, respectively, of the digital signal injected into the start input and the rising or falling edge, respectively, of the digital signal injected into the stop input of the second time-to-digital converter;
h) computing the value of the phase of the complex impedance of the electrical element, either as a function of t₁ for t₁≤S₀, or as a function of t₂ for S₁≤t₁≤S₂, where S₀, S₁ and S₂ are three threshold values, with S₀≤S₁≤S₂.

8. The method according to claim 7, wherein S₀=S₁=T/2 and S₂=T.

9. The method according to claim 7, further comprising the following steps of:
i) injecting the second digital signal (Ū_{I}) into the start input of a third time-to-digital converter and into the stop input of a fourth time-to-digital converter;
j) injecting the first digital signal (Ū_{V}) into the stop input of the third time-to-digital converter and into the start input of the fourth time-to-digital converter;
k) determining a third delay value t₃ between the rising or falling edge, respectively, of the digital signal injected into the start input and the falling or rising edge, respectively, of the digital signal injected into the stop input of the third time-to-digital converter, and a fourth delay value t₄ between the falling or rising edge, respectively, of the digital signal injected into the start input and the rising or falling edge, respectively, of the digital signal injected into the stop input of the fourth time-to-digital converter;
l) computing the value of the phase of the complex impedance of the electrical element, either as a function of t₃ for S₀≤t₁≤S_{0′}, or as a function of t₄ for S_{0′}≤t₁≤S₁, where S_{0′} is a threshold value, with S₀≤S_{0′}≤S₁≤S₂.

10. The method according to claim 9, wherein S₀=T/4, S_{0′}=T/2 and S₁=3T/4 and S₂=T.

11. The method according to claim 10, wherein the delay values are assigned a zero value when they are greater than T/4, and wherein the value of the phase of the complex impedance of the electrical element is determined either as a function of the delay value t₁ for t₁<T/4, or as a function of t₃ for (t₁>T/4 or t₁=0) and t₃<T/4, or as a function of t₄ for (t₁>T/4 or t₁=0), (t₃>T/4 or t₃=0) and t₄<T/4, or as a function of t₂ for (t₁>T/4 or t₁=0), (t₃>T/4 or t₃=0), (t₄>T/4 or t₄=0) and t₂<T/4.
